(19) United States
(12) Patent Application Publication
(10) Pub. No.: US 2023/0384378 A1
(43) Pub. Date: Nov. 30, 2023

(54) SEMICONDUCTOR DEVICE AND SCAN TESTING METHOD

(71) Applicant: RENESAS ELECTRONICS CORPORATION, Tokyo (JP)

(72) Inventor: Yucong ZHANG, Tokyo (JP)

(21) Appl. No.: 17/828,260

(22) Filed: May 31, 2022

(51) Int. Cl. G01R 31/3185

(52) U.S. Cl. CPC G01R 31/318536; G01R 31/318552

(57) ABSTRACT

During the scan testing, the peak power that instantaneously occurs in the shift operation is reduced.

The semiconductor device of the present invention, the phase of the ATE clock signal (ATE_Clk) is shifted in several variations, by external control, as set in the scan testing scan chain has a clock operating unit for distributing the phase shifted clocks.

### BACKGROUND

In recent years, in LSI designs which have become highly integrated, large-scale, and high-speed, it has become indispensable to apply scan test (especially at-speed scan testing), which is one of the test methods for semiconductor integrated circuits, from the viewpoint of reducing the cost required for specification assurance and testing (test).

However, in scan testing, a very large amount of power is consumed in comparison with the function operation (in normal operation). Therefore, it is required to reduce the power consumption during the scan test, and the influence of the peak power and the importance of the reduction are also increasing rapidly.

There are disclosed techniques listed below.
[Patent Document 1] Japanese Unexamined Patent Application Publication No. 2012-185127
[Non-Patent Document 1] Ran Wang, et al., “A Programmable Method for Low-Power Scan Shift in SoC Integrated Circuits.” In Proceedings of the 34th VLSI Test Symposium, April 2016.
[Non-Patent Document 2] Takaki Yoshida, Masafumi Watari, “MD-scan method for low power scan testing.” In Proceedings of the 11th Asian Test Symposium, pp. 80-85, November 2002.

For example, Patent Document 1 aims to reduce the peak power during capture mode in scan testing. For a plurality of circuit blocks, including scan chains and combination circuits, with no data path dependence among them, each block is assigned with a clock selection logic. The clock selection logic can switch between internal PLL clock and a particular scan clock generated by an additional scan clock control logic. The scan clock control logic can generate shift clocks, switching in the same timing, for all blocks during shift mode in scan testing, and generate capture clocks, switching in different timings, for all blocks during capture mode in scan testing. In Patent Document 1, all clocks generated by the scan clock control logic are called block scan clocks.

Furthermore, Non-Patent Document 1 discloses a method to reduce peak power during shift mode in scan testing, in SoC (System on Chip) designs. As shown in FIG. 12, each block of SoC products has a shift stagger circuit that shifts the phase of the shifting clock supplied from a semiconductor testing device (ATE: Automated Test Equipment) in several variations. On/off of the phase shift function of the shift stagger circuit is controlled by an enable signal (enableStagger), and in addition, only one of the variations of the phase shift clock is selected by the selection signal (Stagger_Sel) as the output clock. The selected output clock (StagClkOut) is fed to all scan chains in the block. Thus, by shifting the clock timing of each scan chain, instantaneously high-power consumption can be avoided.

In Non-Patent Document 1, all blocks in a SoC design are divided into adjacent (sharing power supply) and non-adjacent (not sharing power supply) blocks. By assigning different phase shift clocks to all adjacent blocks, peak shift power caused by simultaneous shifting of all blocks can be reduced.

In Non-Patent Document 2, in order to reduce the power supply voltage drop in the shift mode of scan testing, MD-SCAN (Multi Duty-Scan) technique is proposed.

### SUMMARY

The prior art disclosed in Non-Patent Document 1 can prevent all adjacent blocks in the SoC product from using the same phase shift clock, yet test may still fail, in the case of a group contains only one block, and the peak power consumption caused by only testing this block still across the critical line.

Other issues and novel features will be explained in the description of this specification and the accompanying drawings.

According to one embodiment, a semiconductor device is equipped with a clock operator circuit that can shift the phase of the ATE clock signal (ATE_Clk) into several different variations and distribute the phase shifted clock to scan chains scan testing based on external control signals.

According to the one embodiment, a semiconductor device can reduce the peak shift power during scan testing, reducing over-kill and improving the yield.

### BRIEF DESCRIPTION OF THE DRAWINGS

FIG. 1 is a configuration diagram of a semiconductor device according to the first embodiment.

FIG. 2 is a block diagram showing a configuration of a clock operation unit.

FIG. 3 is a block diagram showing a configuration of a clock control unit.

FIG. 4 is a truth table of the multiplexer controlling in the clock control unit.

FIG. 5 is a block diagram showing the configuration of a clock selection unit.

FIG. 6 is a truth table of the multiplexer controlling in the clock selection unit.

FIG. 7 is a design flow diagram in Design-For-Testability (DFT) design flow.

FIG. 8 is a design flow diagram of a clock operation unit.

FIG. 9 is a configuration diagram of a semiconductor device according to the second embodiment.

FIG. 10A is a configuration diagram of a semiconductor device according to the third embodiment.

FIG. 10B is a graph of the peak voltage drop in the semiconductor device according to the third embodiment.

FIG. 11A is a configuration diagram of a semiconductor device according to the third embodiment.

FIG. 11B is a graph of the peak voltage drop in the semiconductor device according to the third embodiment.

FIG. 12 is a diagram for explaining the operation according to the prior art (Non-Patent Document 1).

### DETAILED DESCRIPTION

Hereinafter, a semiconductor device according to an embodiment will be described in detail by referring to the drawings. In the specification and the drawings, the same or corresponding form elements are denoted by the same reference numerals, and a repetitive description thereof is omitted. In the drawings, for convenience of description, the configuration may be omitted or simplified. Also, at least some of the embodiments may be arbitrarily combined with each other.

### First Embodiment

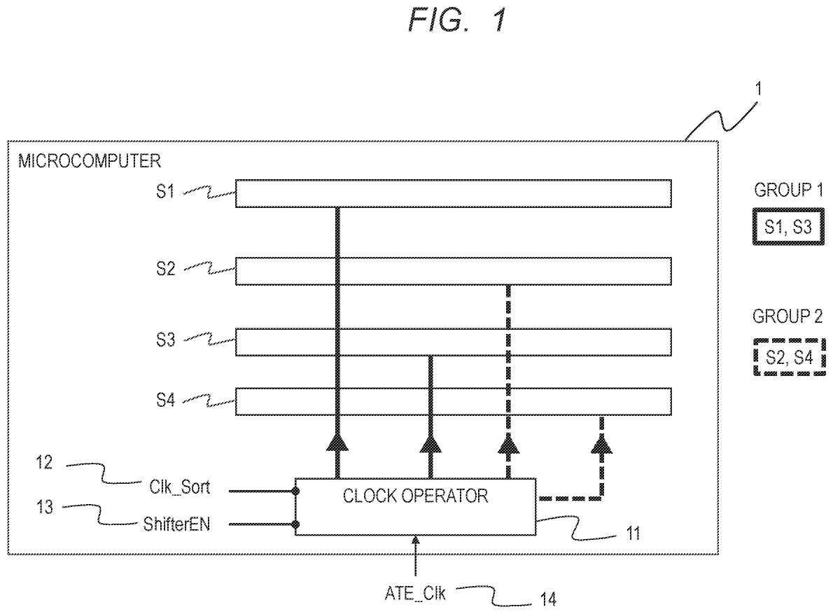

FIG. 1 is a block diagram showing a configuration of a semiconductor device according to the first embodiment.

In the first embodiment, as an example of a semiconductor device, microcomputer 1 will be described. Microcomputer 1 as a semiconductor device, for example, a semiconductor substrate (semiconductor chip) such as a single-crystal silicon, is formed using a known CMOS manufacturing process. Microcomputer 1 includes a plurality of scan chains S1, S2, S3, S4, and Clock Operator 11 to shift the phase of ATE clock signal 14 (ATE_Clk) supplied from a tester (not shown) and distributing the signals to the scan chains.

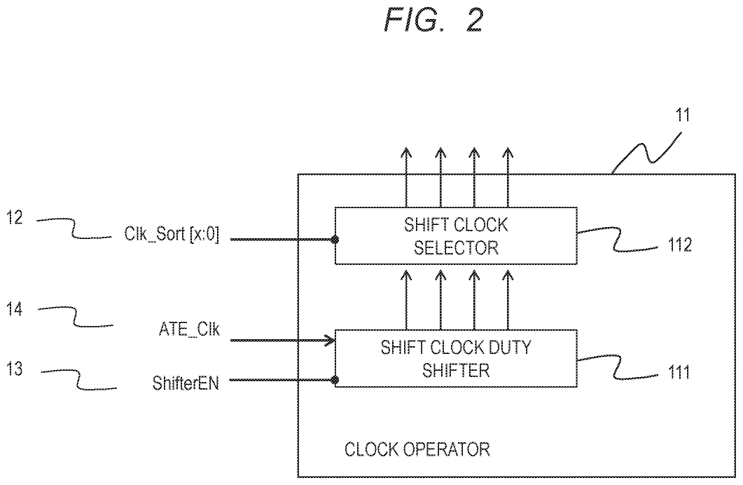

FIG. 2 is a block diagram illustrating a configuration of Clock Operator 11. Clock Operator 11 includes Shift Clock Duty Shifter 111 for shifting the phase of the supplied ATE clock signal 14 (ATE_Clk) into several variations, and Shift Clock Selector 112 for distributing phase shifted clock signals to each scan chain in accordance with the order specified by external control signals.

Shift Clock Duty Shifter 111 is controlled by shift control signal 13 (ShifterEN), if shift control signal 13 (ShifterEN) is ON, the phase of the supplied ATE clock signal 14 (ATE_Clk) will be shifted. On the other hand, when shift control signal 13 (ShifterEN) is OFF, it outputs ATE clock signal 14 (ATE_Clk) without changing its phase.

Shift Clock Selector 112 is controlled by clock sort signal 12 (Clk_Sort[x:0]) and selects the input ATE clock signal 14 (ATE_Clk) in the defined order and outputs it to the clock port of each scan chain. Here, the value of x is determined by the number of the phase shifted clocks c (c>1) and the number of scan chains s; More specifically, x=(√c)*s.

(Operation of the Shift Clock Duty Shifter)

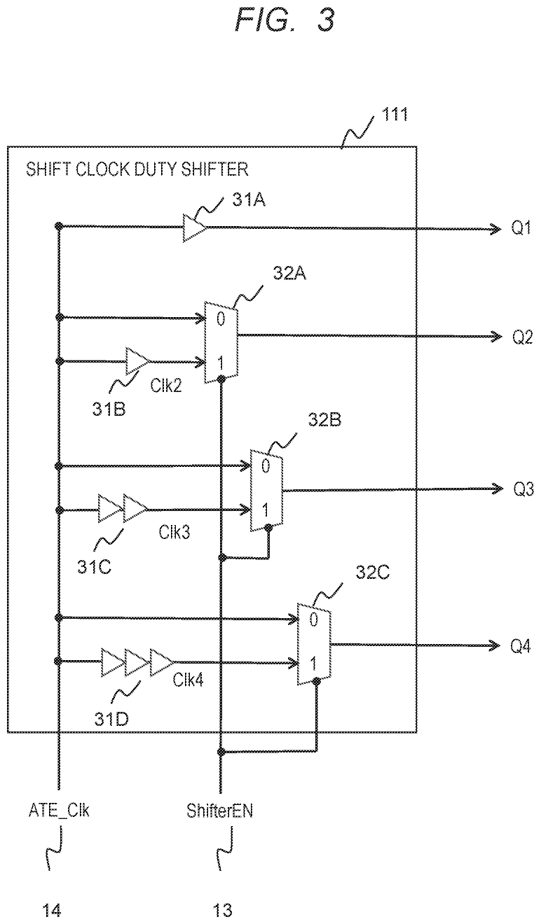

FIG. 3 is a circuit diagram showing a configuration of Shift Clock Duty Shifter 111. Shift Clock Duty Shifter 111, for example, can be implemented by combining a set of clock buffers and multiplexers.

In the example shown in FIG. 3, the input ATE clock signal 14 (ATE_Clk) branches and go through clock buffers 31A, 31B, 31C, 31D. Clock buffers 31A, 31B, 31C, 31D are formed by delay elements, shifting the phase of ATE clock signal 14 (ATE_Clk). The outputs of multiplexers 32A, 32B, 32C are controlled by shift control signal 13 (ShifterEN), they can switch freely between ATE clock signal 14 (ATE_Clk) and the phase shift clocks.

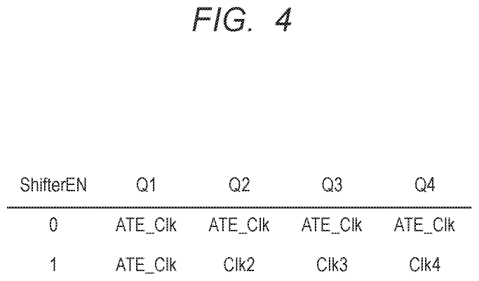

As the truth table of FIG. 4 shows, when shift control signal 13 (ShifterEN) is 0, from the outputs Q1, Q2, Q3, Q4 of Shift Clock Duty Shifter 111, ATE clock signal (ATE_Clk) is output without phase shifting. In contrast, when shift control signal 13 (ShifterEN) is 1, among the outputs of Shift Clock Duty Shifter 111, Q1 outputs ATE clock signal 14 (ATE_Clk) and Q2, Q3, Q4 output the phase shifted clock signal 2 (Clk2), clock signal 3 (Clk3), and clock signal 4 (Clk4), respectively. The buffer implemented in the output path of Q1 is for adjusting the clock skew.

(Operation of Shift Clock Selector)

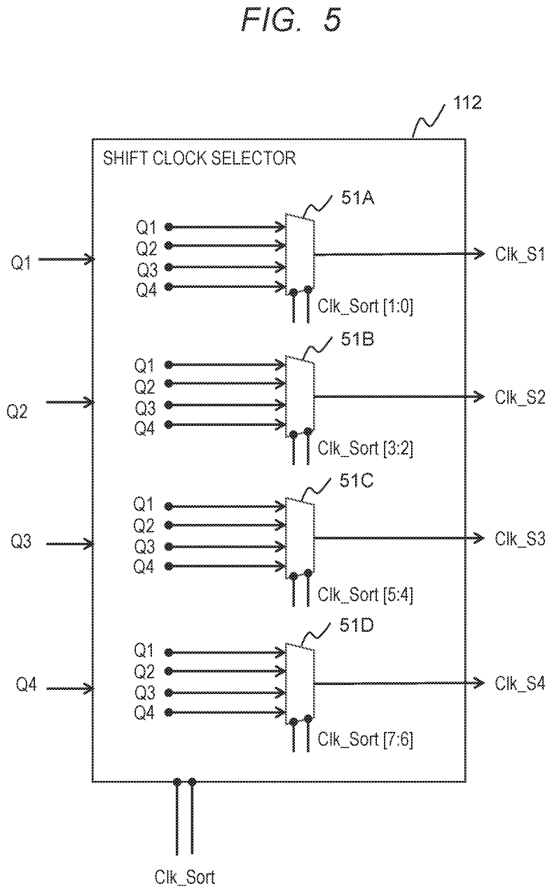

FIG. 5 is a circuit diagram showing an example of Shift Clock Selector 112. Shift Clock Selector 112 is implemented, for example, by a combination of a four-input one-output multiplexer and the corresponding clock sort signal Clk_Sort[1:0].

In the example illustrated in FIG. 5, the outputs Q1, Q2, Q3, Q4 of the Shift Clock Duty Shifter 111 are input, and the multiplexers 51A, 51B, 51C, 51D can freely switch the Q1, Q2, Q3, Q4 inputs by the clock sort signal (Clk_Sort).

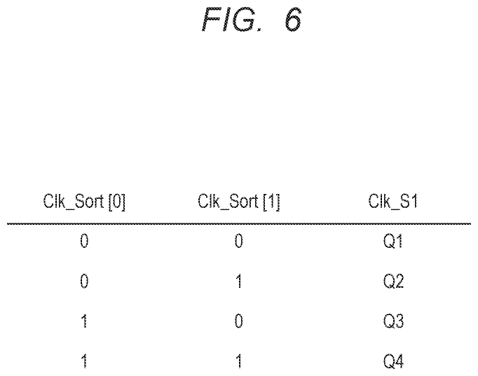

The truth table of FIG. 6 shows an example of the operation of a four-input one-output multiplexer. Q1 is selected when the clock sort signal Clk_Sort[1:0] is “00”, Q2 is selected when the clock sort signal Clk_Sort[1:0] is “01”, Q3 is selected when the clock sort signal Clk_Sort[1:0] is “10”, and Q4 is selected when the clock sort signal Clk_Sort[1:0] is “11”. Although the ATE clock signal 14 in the first embodiment (ATE_Clk) is divided into four variations, it can be less than or more than four.

(Explanation of Design Flow 1)

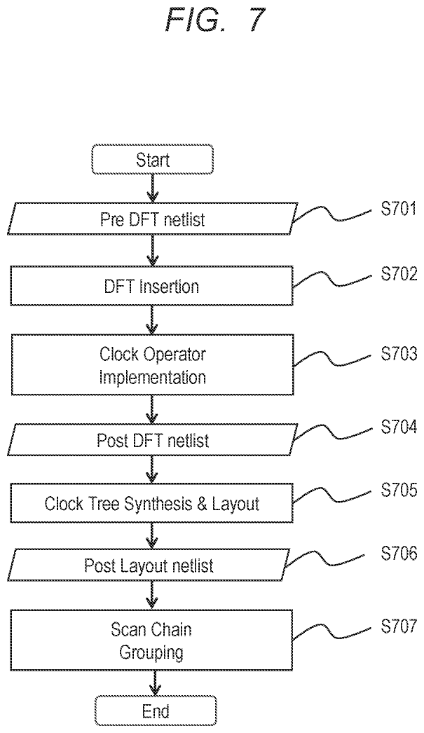

FIG. 7 is a diagram illustrating an implementation flow in Design-For-Testability (DFT) design of microcomputer 1. Incidentally, the standard design steps that are not directly related to the present invention are omitted.

For the pre-DFT netlist (gate level) of microcomputer 1 in FIG. 7, first, a normal scan-based DFT circuit implementation is performed (step S702). Thereafter, Clock Operator 11 is implemented according to the granularity of the shift clock to be controlled (in unit of one per scan chain or one per group of multiple scan chains) (step S703).

The above steps generate a post DFT netlist of microcomputer 1 (step S704), and for the generated post DFT netlist (step S705), a clock tree is implemented by clock tree synthesis. Here, as an application condition of the present invention, the sub clock trees from Clock Operator 11 to each scan chain or scan chain group need to be independent from each other. After clock tree synthesis, P&R (Place & Route) is executed for the netlist and a post-layout netlist is generated (step S706). Finally, the scan chain grouping considering the layout information which can maximize the reduction of the peak shift power is calculated, and the grouping result is applied through the external control in the scan testing.

(Explanation of Design Flow 2)

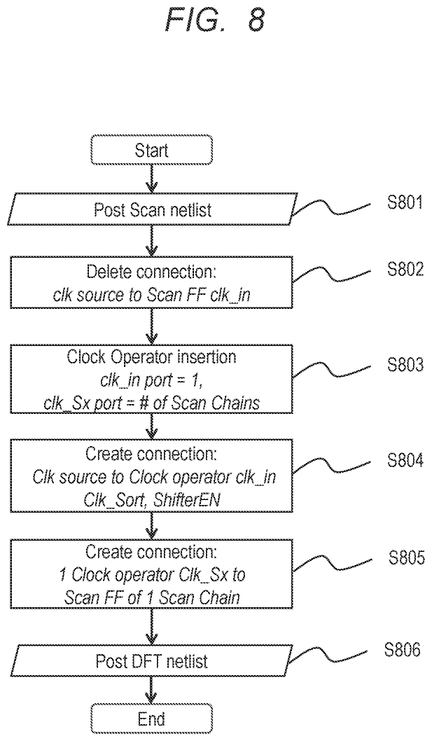

FIG. 8 is a diagram illustrating a design flow of Clock Operator 11 of microcomputer 1. Incidentally, the standard design steps that are not directly related to the present invention are omitted.

In FIG. 8, each two steps are connected by an arrow, it appears that these steps are performed in a time series according to the direction of the arrow.

For a post scan netlist implemented with scan design-based DFT circuit of microcomputer 1, the connection between clock source (Clk source) and the clock input of each scan FF is first deleted (step S802). Then, clock operator module with clock outputs (Clk_Sx (x=1, 2, . . . , n)) are generated and implemented in accordance with the number of scan chains, n (step S803). Here, clock source (Clk source), Clk_Sort and shift control signal (ShifterEN) are connected to the inputs of Clock Operator 11 (step S804). Further, as the output side of Clock Operator 11, each clock output (Clk_Sx) is connected to clock input (clk_in) of all scan FF of scan chain Sx (step S805). The above steps generate a post DFT netlist of microcomputer 1.

(Effect of the First Embodiment)

During the shift operation of the scan test, in microcomputer 1, it is possible to reduce the peak power consumption caused instantaneously by the toggle timing to shift the scan FF belonging to each scan chain.

Furthermore, On/Off of the phase shift function of the shift clock can be controlled by shift control signal (ShifterEN).

In addition, in order to realize the function of independently controlling the clocks of each scan chain, the sub clock trees fanning out from the Clock Operator to each scan chain must be independent from each other.

### Second Embodiment

In the second embodiment, the semiconductor device shows a configuration capable of coping with a design having a plurality of clock domains.

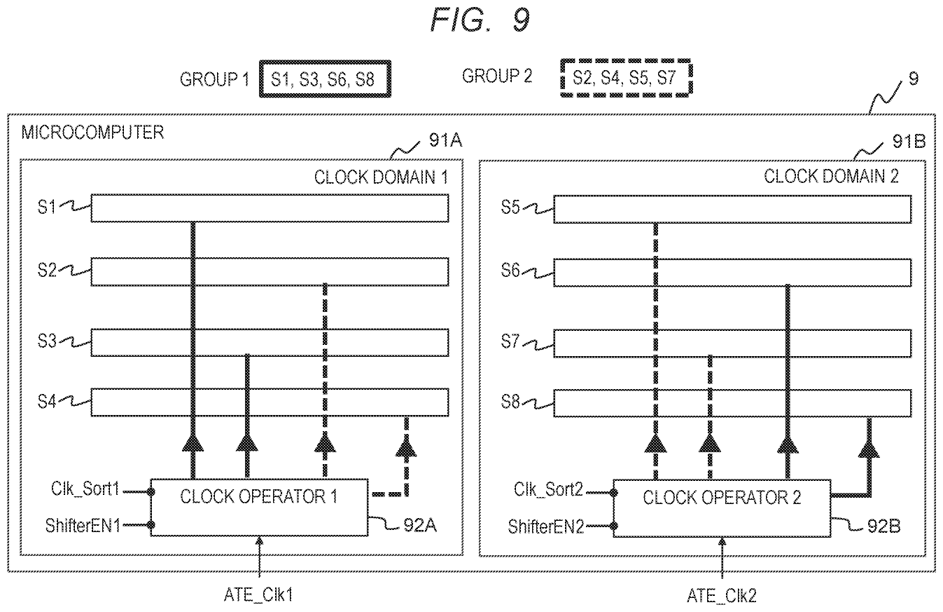

FIG. 9 shows a configuration diagram of a semiconductor device in the second embodiment. Compare with the case of the first embodiment, microcomputer 9 is different in the point that it comprises a plurality of clock domains therein. If more than one clock domains exist, multiple Clock Operators need to be implemented corresponding to the number of clock domains.

As shown in FIG. 9, microcomputer 9 includes two clock domains (91A, 91B), and each clock domain has a plurality of scan chains. The first clock domain (91A) has scan chains S1, S2, S3, S4, and the second clock domain (91B) has scan chains S5, S6, S7, S8.

Clock Operator 1 (92A) has shift control signal 1 (ShifterEN1) and ATE clock signal 1 (ATE_Clk1). Clock Operator 2 (92B) has shift control signal 2 (ShifterEN2) and ATE clock signal 2 (ATE_Clk2).

Furthermore, in order to control the clock of scan chain, the clock sort signal (Clk_Sort[x:0]) of the first embodiment is divided into clock sort signal 1 (Clk_Sort1[y:0]) and clock sort signal 2 (Clk_Sort2 [x:y]), being assigned to Clock Operator 1 (92A) and Clock Operator 2 (92B), respectively. In the second embodiment, but this is not a limitation for applying the present invention.

During the shift operation in scan testing, it is not always necessary to input the same clock to ATE clock signal 1 (ATE_Clk1) and ATE clock signal 2 (ATE_Clk2). By shifting the phase of ATE clock signal 1 (ATE_Clk1) and ATE clock signal 2 (ATE_Clk2) in advance, the variation of clocks generated from Clock Operator 1 (92A) and Clock Operator 2 (92B) can be increased. As a result, the structure of Clock Operators can be simplified, and it is possible to increase the degree of freedom in performing scan chain grouping.

In addition, since the values of clock sort signal 1 (Clk_Sort1) and clock sort signal 2 (Clk_Sort2) can be changed by external control, it is also possible to change them by the test pattern (wafer test, assembly test, different tester types, etc.). Thus, even after semiconductor products are manufactured, shift power consumption reduction can be realized according to the actual situation, dynamically.

Furthermore, when microcomputer 1 is a SoC, the control of shift control signal 1 (ShifterEN1) and shift control signal 2 (ShifterEN2) also allows control in block units as in the prior art.

(Effect of the Second Embodiment)

The second embodiment can accommodate a larger scale design compare to the first embodiment. In addition, it can correspond to more complicated clock designs.

### Third Embodiment

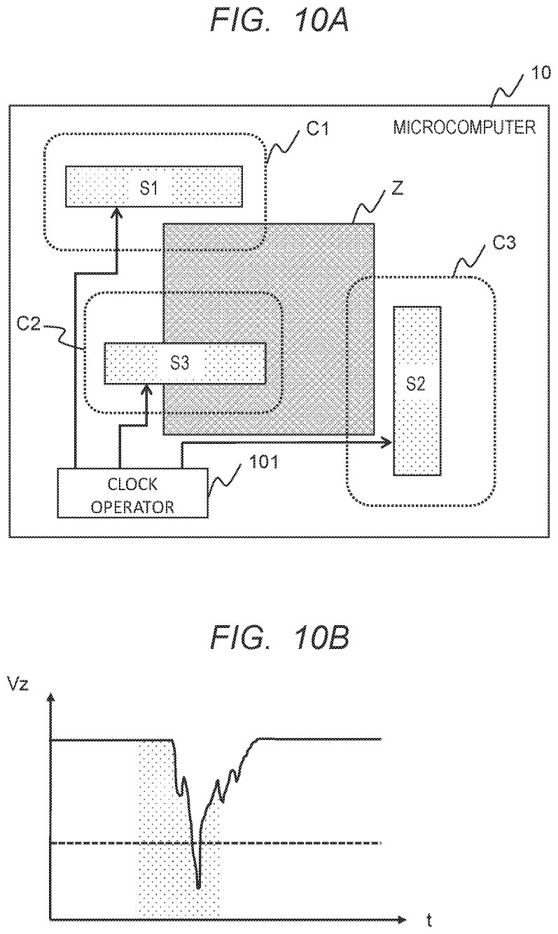

FIG. 10A is a block diagram showing a configuration of a semiconductor device according to the third embodiment. In this case, an example of the semiconductor device is microcomputer 10 equipped with Clock Operator 101 that can output two types of phase shifted clocks.

In microcomputer 10, there is an optimization area Z that is particularly sensitive to voltage drop (V-drop), scan chains S1, S2, S3 and their output cones C1, C2, C3. The optimization area Z is an LSI design-dependent region, for example, the central area of the chip where the power supply is weak, the area where the logic paths are dense, the area where there is a critical path which is hard to meet the timing constraint, or other reasons. The output cone refers to all logic paths from the output port of the FF belonging to each scan chain to the input port of any FF or the output port of the circuit. Output cones C1, C2, C3 overlap with the optimization area Z, respectively. In the overlapped areas switching activity can occur during shift operation.

During shift operation, if the Clock Operator is “On” (e.g. shift control signal (ShifterEN) is “1”), the generated two shift clocks need to be assigned to scan chain S1, S2, S3. As a result, it is necessary to group the scan chains.

After scan chain grouping, the overlap area of each scan chain group should be minimized to suppress the voltage drop (V-drop) of the optimization area Z. Such grouping is the most suitable one.

As shown in FIG. 10B, when all scan chains S1, S2, S3 perform shift operation at the same timing by the same shift clock, the voltage drop (V-drop) in the optimization area Z exceeds the threshold.

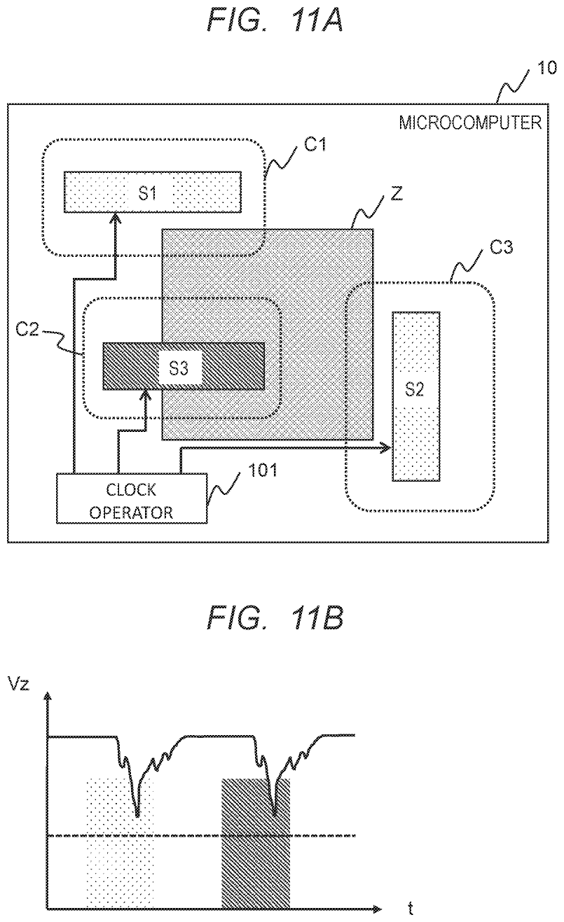

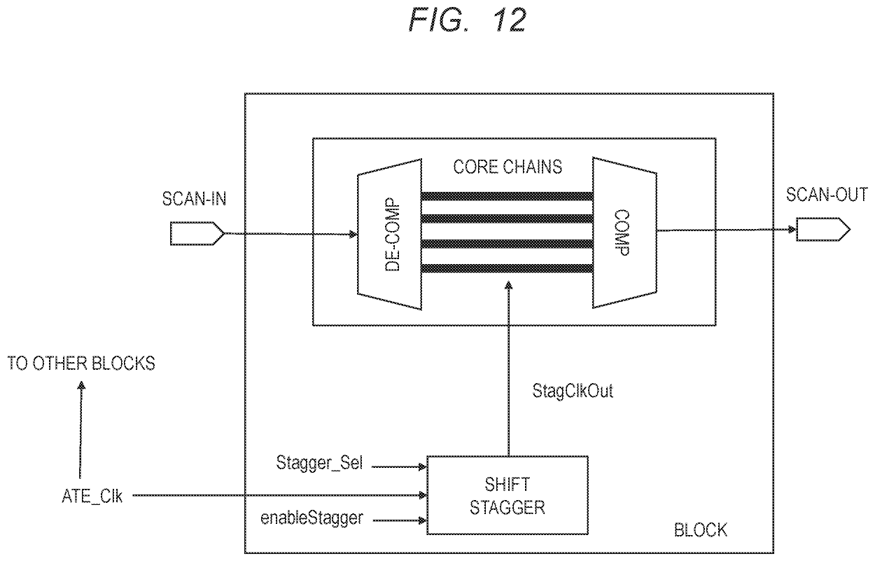

On the other hand, FIG. 11A shows a case where the scan chains S1, S2 and the scan chain S3 perform shift operation at different timings by the control of Clock Operator 101. When the shift operation is performed at different timings, as shown in FIG. 11B, the voltage drop (V-drop) within the optimization area Z falls within a predetermined range.

As a result, the reduction effect of peak shift power can be maximized with less shift clock variations.

In examples of FIG. 10A and FIG. 11A, one optimization area is one, but there may be a plurality of optimization areas.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a plurality of circuit blocks to form a scan chain during a scan testing;
a clock operator for supplying a clock to the scan chain during the scan testing,
wherein the clock operator shifts a clock signal supplied from a tester during the scan testing based on a combination with a shift control signal for shifting the phase of the clock signal and a clock sort signal for setting an output timing of the clock signal, and outputs a shifted clock signal to a port of the scan chain.

2. The semiconductor device according to claim 1,
is the clock operator further comprising:
a clock control unit for inputting the clock signal and the shift control signal and outputting a shifted signal obtained by shifting the clock signal by the shift control signal, and
a clock selection unit for outputting the shifted signal by the clock sort signal at a set timing.

3. The semiconductor device according to claim 2,
the clock control unit comprising:
first to fourth multiplexers for inputting a delay clock signal obtained by delaying the clock signal with a predetermined timing,
wherein each of the first to fourth multiplexers outputs either the clock signal or the delay clock signal in accordance with the shift control signal as a first to fourth shifted clock signal.

4. The semiconductor device according to claim 3,
when the shift control signal is 0, each of the first to fourth multiplexers outputs the clock signal as the first to fourth shifted clock signal,
when the shift control signal is 1, each of the first to fourth multiplexers outputs the delay clock signal as the first fourth shifted clock signal.

5. The semiconductor device according to claim 3,
wherein each of the first to fourth multiplexers inputs the delayed clock signals with different timing delays.

6. The semiconductor device according to claim 3,
the clock selection unit has fifth to eighth multiplexers for inputting the first to fourth shifted clock signal and the clock sort signal,
wherein each of the fifth to eighth multiplexers outputs one of the first to fourth shifted clock signals in accordance with the clock sort signal.

7. The semiconductor device according to claim 4,
wherein the scan chains formed in the plurality of circuit blocks are grouped, one of the first to fourth shifted clock signals is input for each scan chain belonging to each group.

8. A semiconductor device comprising a plurality of clock domains, wherein each of the plurality of clock domains has a plurality of circuit blocks to form a scan chain during a scan testing,
a clock operator for supplying a clock to the scan chain during the scan testing,
wherein the clock operator shifts a clock signal supplied from a tester during the scan testing based on a combination with a shift control signal for shifting the phase of the clock signal and a clock sort signal for setting an output timing of the clock signal, and outputs a shifted clock signal to a port of the scan chain,
wherein the scan chains formed in the plurality of circuit blocks in the plurality of clock domains are grouped, and
the clock signal is provided at a timing that becomes for each scan chain belonging to each group.

9. The semiconductor device comprising a plurality of power supply areas,
wherein each of the plurality of power supply areas has a plurality of circuit blocks to form a scan chain during a scan testing,
a clock operator for supplying a clock to the scan chain during the scan testing,
wherein the clock operator shifts a clock signal supplied from a tester during the scan testing based on a combination with a shift control signal for shifting the phase of the clock signal and a clock sort signal for setting an output timing of the clock signal, and outputs a shifted clock signal to a port of the scan chain,
wherein each of the plurality of circuit blocks belongs to either a first block group including a specific area or a second block not including the specific area,
the clock signal is provided at different timing for each scan chain that belongs to each group.

10. The semiconductor device of according to claim 9,
wherein the specific area is either an area where power supply is weakened, an area where logic circuits are dense, or a area where there are tight paths in timing.

11. A scan testing method in a semiconductor device,
a plurality of circuit blocks to form a scan chain during the scan testing,
a clock operation unit for supplying a clock to the scan chain during the scan testing,
wherein the clock operator shifts a clock signal supplied from a tester during the scan testing based on a combination with a shift control signal for shifting the phase of the clock signal and a clock sort signal for setting an output timing of the clock signal, and outputs a shifted clock signal to a port of the scan chain,
wherein the scan chains formed in the plurality of circuit blocks are grouped, and the control operator outputs the shifted clock signal different for each scan chain belonging to each group.

12. A scan testing method in a semiconductor device having a plurality of clock domains,
wherein each of the plurality of clock domains,
a plurality of circuit blocks to form a scan chain during the scan testing,
wherein the clock operator shifts a clock signal supplied from a tester during the scan testing based on a combination with a shift control signal for shifting the phase of the clock signal and a clock sort signal for setting an output timing of the clock signal, and outputs a shifted clock signal to a port of the scan chain,
wherein the scan chain formed in the plurality of circuit blocks in the plurality of clock domains are grouped, and
the clock signal is provided at a timing that becomes for each scan chain belonging to each group.

13. A scan testing method in a semiconductor device having a plurality of power supply areas,
wherein each of the plurality of power supply areas,
a plurality of circuit blocks to form a scan chain during the scan testing,
wherein the clock operator shifts a clock signal supplied from a tester during the scan testing based on a combination with a shift control signal for shifting the phase of the clock signal and a clock sort signal for setting an output timing of the clock signal, and outputs a shifted clock signal to a port of the scan chain,
wherein each of the plurality of circuit blocks belongs to either a first block group including a specific area or a second block not including the specific area,
the clock signal is provided at different timing for each scan chain that belongs to each group.
